(19) United States
(12) Patent Application Publication
(10) Pub. No.: US 2023/0226917 A1
(43) Pub. Date: Jul. 20, 2023

(54) METHOD FOR DETECTING AN INSULATION FAULT IN A VEHICLE ON-BOARD ELECTRICAL SYSTEM

(71) Applicant: Vitesco Technologies GmbH, Regensburg (DE)

(72) Inventor: Franz Pfeilschifter, München (DE)

(21) Appl. No.: 17/928,786

(22) PCT Filed: May 31, 2021
(86) PCT No.: PCT/EP2021/064582

§ 371 Date: Nov. 30, 2022

(30) Foreign Application Priority Data
Jun. 3, 2020 (DE) 10 2020 206 953.0

(51) Int. Cl. B60L 3/00; B60L 58/20; G01R 31/52

(52) U.S. Cl. CPC B60L 3/0069; B60L 58/20; G01R 31/52

(57) ABSTRACT

A method for detecting an insulation fault in a vehicle on-board electrical system having an HV on-board electrical system branch and an LV on-board electrical system branch provides for the LV on-board electrical system branch to have a positive supply potential and a negative supply potential that corresponds to a ground potential of the vehicle on-board electrical system. The HV on-board electrical system branch has a positive HV potential and a negative HV potential which are DC-isolated from the potentials of the LV on-board electrical system branch. An insulation fault between at least one of the HV potentials and a positive LV potential is detected by identifying a current flow through a voltage limiting circuit connected between the ground potential and the positive LV potential.

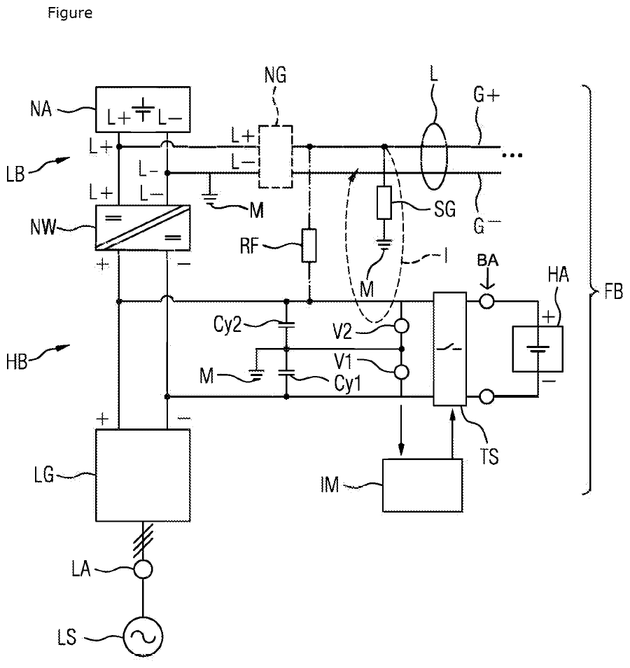

### CROSS REFERENCE TO RELATED APPLICATIONS

This application is the U.S. National Phase application of PCT International Application No. PCT/EP2021/064582, filed May 31, 2021, which claims priority to German Patent Application No. 10 2020 206 953.0, filed Jun. 3, 2020, the contents of such applications being incorporated by reference herein.

### FIELD OF THE INVENTION

The present invention relates to a method for detecting an insulation fault in a vehicle on-board electrical system having high voltage on-board electrical system branch and an low voltage on-board electrical system branch.

### BACKGROUND OF THE INVENTION

It is known practice to equip vehicles with an electrical drive or other electrical components. In order to achieve high powers, particularly for traction, use is made of high voltages, for example of 400 volts or more, which, in contrast to the otherwise customary 12 volt on-board electrical systems, can pose a risk to people.

For this reason, vehicles that have a high-voltage on-board electrical system (i.e. a high-voltage on-board electrical system—HV on-board electrical system) are provided with insulation that electrically separates the HV on-board electrical system from the rest of the on-board electrical system and the ground potential, in particular from the vehicle chassis.

Since a fault in the insulation can result in a contact voltage which is harmful if not fatal to humans, further mechanisms for monitoring this insulation are provided. Such insulation monitoring captures the two HV potentials of the HV system with respect to ground in order to thus determine insulation resistances with respect to ground (chassis). However, if there is a high-impedance insulation fault, part of the low-voltage on-board electrical system can be connected to a dangerous HV potential without being detected.

### SUMMARY OF THE INVENTION

It is an aim of the invention to show a possibility with which an insulation fault between an HV on-board electrical system branch and a low-voltage on-board electrical system branch (LV on-board electrical system branch) can be detected, especially if the insulation fault has a high impedance.

It is proposed to provide a voltage limiting circuit in the LV on-board electrical system branch (corresponding to a low-voltage on-board electrical system branch) so that a current flow through this circuit indicates that an HV potential is connected to a supply potential of the LV on-board electrical system branch. For example, a communication, control, or sensor component within the LV on-board electrical system branch can come into contact with an HV potential due to an insulation fault. However, depending on the component, it may burn out with no noticeable or monitored current flow, with the result that, although the LV potential does not come into contact with the rest of the LV on-board electrical system branch due to the burnt-out component, a wire or other component of the LV on-board electrical system carries the HV potential. The voltage limiting circuit therefore provides a dedicated and reliable element which causes a detectable and reliable current flow if an HV potential comes into contact with the potential of the LV on-board electrical system branch due to insulation faults. If, for example, a line of a low-voltage sensor device (or of another LV device) that is connected to the LV on-board electrical system branch comes into contact with an HV potential due to an insulation fault, an input stage (more generally: data or measurement interface) of the sensor device, to which the sensor line is connected, may burn out unnoticed, with the result that there is no current flow between the HV on-board electrical system branch and the LV on-board electrical system branch. However, the sensor line remains at the HV potential due to the insulation fault and there is also no detectable current flow due to the burnt-out input stage. An HV potential could then reach other components via this sensor line, in particular since the sensor device and its line are not designed for high-voltage applications and therefore also have no appropriate insulation. The same applies to communication or control devices of the LV on-board electrical system branch and their interface.

The method proposed here makes it possible to generate a current flow in a targeted manner using the voltage limiting circuit, which current flow does not depend on the burn-out behavior, for example, of a (data) interface of a sensor device, of an interface of a communication device or of a control device or of other elements of the LV on-board electrical system branch when an HV potential reaches this. The voltage limiting circuit allows a current flow to be identified in a detectable and reliable manner, which current flow indicates that an HV potential has been applied to a component of the LV on-board electrical system branch.

In particular, the voltage limiting circuit can be easily adapted to the voltage of the HV on-board electrical system, which is not the case for LV components. Such an adaptation would be, for example, a design in which a defined current flow passes through the voltage limiting circuit when an HV voltage (voltage between HV+ and HV− or between ground and HV+ or HV−) is applied to said circuit. The procedure described here makes it possible in particular to identify when an HV potential is applied to a component of the LV on-board electrical system branch (e.g. a control, communication or sensor component), even if no detectable current is flowing due to the insulation fault. For example, an active measurement of the insulation resistance would not reliably detect such a sensor error, especially if the connection between the line connected to the LV component (low voltage) and the rest of the LV on-board electrical system branch is lost due to a component part in the LV component burning out. The terms LV component and LV device (e.g. in control, communication or sensor devices) are synonyms here.

A method for detecting an insulation fault in a vehicle on-board electrical system is therefore described. In this case, the vehicle on-board electrical system has an HV on-board electrical system branch and an LV on-board electrical system branch. The HV on-board electrical system branch can also be referred to as a high-voltage on-board electrical system branch. The LV on-board electrical system branch can also be referred to as a low-voltage on-board electrical system branch. The prefix “high-voltage” or “HV” defines components or on-board electrical system branches or sections thereof that work with operating voltages of more than 60 volts, in particular at least 200, 400, 600, 800 or 100 volts. These pose a danger to people if they come into contact with the operating voltage. The prefixes “LV” and “low-voltage” are synonymous and mean an operating voltage of less than 60 volts, in particular, for example, 12 to 14 volts, essentially 24 volts or essentially 48 volts. These operating voltages do not require any special measures to avoid contact with the operating voltage in question.

The LV on-board electrical system branch has a positive supply potential and a negative supply potential. The negative supply potential corresponds to a ground potential of the vehicle on-board electrical system, in particular the chassis potential. The HV on-board electrical system branch has a positive and a negative HV potential. These two HV potentials are DC-isolated from the potentials of the LV on-board electrical system branch. This DC isolation is based in particular on (electrical) insulation, and it is described here how a fault in this insulation can be detected. The HV potentials are not related to the ground potential in order to thus avoid a dangerous current upon contact.

An insulation fault between at least the HV potentials and a positive LV potential is detected. In this case, an LV potential that is positive with respect to ground as a supply potential is referred to as a positive LV potential, as are potentials that are not ground, for instance signal potentials such as control, data or measurement signals, since these are usually positive with respect to ground. However, these can also be negative with respect to ground, at least temporarily, depending on the specific characteristics of the on-board electrical system and the transmitted signal.

The HV potentials are supply potentials. As mentioned, the LV potential can be a positive LV supply potential, but can also be a potential of a conductor, for example a sensor, communication or control conductor, or of another component. The insulation fault is detected by identifying a current flow through a voltage limiting circuit. This voltage limiting circuit is connected between the ground potential and the positive LV potential (that is to say the potential to be monitored). The voltage limiting circuit is configured not to conduct below a breakdown voltage and to conduct above this voltage. As a result, the current flow indicates an excessively high voltage, i.e. a voltage above a breakdown voltage of the voltage limiting circuit.

This breakdown voltage is greater than the maximum operating voltage or nominal voltage of the LV on-board electrical system branch, with the result that a current flow only occurs when the positive LV potential has an excessively high voltage with respect to ground. In this case, an excessively high voltage is a voltage that is above the breakdown voltage, in particular that is above a predefined value or above the maximum operating voltage of the LV on-board electrical system branch. Since the voltage limiting circuit is equipped with specific features, namely a current flow above a certain breakdown voltage, while components or devices such as sensor evaluation circuits, communication circuits, control circuits and the like, for example, do not necessarily have these features, the voltage limiting circuit can be used to reliably identify an excessively high voltage at the positive LV potential even if otherwise no current flows from the HV on-board electrical system branch to ground, that is to say even if the fault cannot be clearly identified by active insulation resistance measurement. In particular, the interfaces in question, which are used to connect a line to the component in question, do not have a reliable behavior in the event of overvoltage, especially since these are also designed for a low voltage (<60 V).

One embodiment provides for the current flow to be identified on the basis of a shift of one of the HV potentials with respect to the ground potential. This is determined by a passive voltage measurement of the HV potentials with respect to the ground potential. In this case, only one HV potential can also be measured with respect to the ground potential. In particular, an HV potential can be determined by capturing the voltages between the HV potentials and by subtracting the voltage between the other HV potentials and ground potential.

The voltage limiting circuit uses the current flow to generate a shift of at least one of the HV potentials with respect to ground potential in a targeted manner if there is an insulation fault between an HV potential and a positive LV potential. In the absence of a voltage limiting circuit, this would depend on the property of the LV component where the positive LV potential is provided, in particular whether this component will generate a reliable current flow in the event of overvoltage at the LV potential, or whether the component does not generate a corresponding current flow in the event of an excessively high voltage at the LV potential as a result of a component part (of an interface of an LV component or of an LV component itself) or a fuse burning out or blowing.

The current flow through the voltage limiting circuit can also be identified on the basis of a potential change rate that is above a predetermined value. The potential change rate indicates the extent to which the charge of the Cy capacitances (parasitic or dedicated filter capacitors) is reversed when the current flows. The predetermined value, on the basis of which the current flow is identified, is in particular above a value that occurs at the maximum potential change rate during active insulation measurement. In particular, the potential change rate is the rate at which the voltage between one of the HV potentials changes with respect to the ground potential over time. In this case, the predetermined value can be at least 100 volts/ms, 500 volts/ms, 100 volts/ms or at least 100 volts/μs. According to the method provided here, no current flow is identified if the potential change rate is below the predetermined value.

Alternatively or in combination with this, the current flow can be identified by the magnitude of the potential difference that results from the change, i.e. the potential difference that results after the change. This corresponds to the steady-state case of the potential change, i.e. the potential difference after the potential change. The current flow can thus be identified on the basis of a change to a potential difference between the HV potential and the ground potential. The current flow is identified when the resulting potential difference is below a predetermined value. This potential difference is preferably detected while the voltage between the HV potentials is within a normal range. In this case, the normal range corresponds, for example, to the standard operating voltage. In this case, the predetermined value can be, for example, a maximum of 60 volts, 50 volts, 30 volts or 20 volts, in particular a maximum of 20 volts or 16 volts. In one exemplary embodiment, the predetermined value is approximately 60 volts, 50 volts or 40 volts or else 20 V or 16 V. The predetermined value is preferably below the minimum value that occurs during an active insulation measurement.

One embodiment provides for the shift to be identified by means of an insulation monitor or by means of at least one voltmeter, which are part of the insulation monitor or are connected to the latter.

Provision may be made for the insulation monitor to also carry out an active insulation test of the HV on-board electrical system branch. This is carried out by actively reversing the charge of or discharging (or charging) Cy capacitances between ground on the one hand and the HV potentials on the other hand. The Cy capacitances can be composed of parasitic capacitances and dedicated filters, as are used in EMC filters, for example. Since the level of the Cy capacitances is essentially known, the likewise known current of the active charge reversal or discharging results in a potential change rate (between ground on the one hand and at least one HV potential on the other) which is characteristic of the insulation resistance. The active insulation test is therefore a test of the discharge or charging rate of the Cy capacitances when the test current is applied. The test current is preferably generated or at least controlled by an insulation monitor. The active insulation test also provides for detection of a potential shift that results from the charge reversal. This concerns a shift of an HV potential with respect to ground. Since the insulation monitor detects the potential shift of the HV potentials with respect to the ground potential, it can also be used to identify a current flow through the voltage limiting circuit.

A further aspect is that the active charge reversal or discharging is interrupted by the insulation monitor when a current flow through the voltage limiting circuit is identified. In this case, the current flow can be identified in particular by means of a potential shift that results from the current flow through the voltage limiting circuit. In this case, it is possible to use at least one voltmeter that is also used for the active insulation test of the insulation monitor, or it is possible to use at least one voltmeter that is not evaluated by the insulation monitor.

A potential difference between one of the HV potentials and the ground potential preferably does not drop below a minimum voltage during the active charge reversal. This applies in particular to their magnitudes. The minimum voltage for an HV on-board electrical system branch with a nominal voltage of 800 V is, for example, at least 60 V or 100 V. The minimum voltage caused by the active insulation test is at least 7%, 8%, 10% or 15% of the nominal voltage of the HV on-board electrical system. The current flow through the voltage limiting circuit is preferably identified on the basis of a change to a potential difference between the HV potential and the ground potential that is below a predetermined value. In particular, this value is smaller than the minimum voltage. In the case of an HV on-board electrical system branch with a nominal voltage of 800 V, this value is, for example, a maximum of 15 volts, 16 volts, 20 volts or 25 volts, possibly also 30 volts or 40 volts or 50 volts (in particular less than 60 volts). The range from which the minimum voltage is selected is above the range from which the predetermined value is selected.

In other words, although the charge is reversed (concerning the Cy capacitors) by the insulation monitor during the active insulation resistance measurement and the minimum voltage can result, the active insulation measurement does not result in a voltage value that would be relevant for detecting a current flow through the voltage limiting circuit (=predetermined value). Rather, when a current flows through the voltage limiting circuit, a current flows that results in a potential difference that is smaller (roughly by a predetermined margin) than the minimum voltage that occurs in the usual active insulation resistance measurement (for short: insulation measurement). This allows the different measurements to be distinguished and different types of error can also be output, namely a first error if the voltage value is below the predetermined value and a second error if the insulation resistance measurement results in a resistance value which is below a resistance limit value.

Provision can be made for the current flow through the voltage limiting circuit to be identified by measuring at least one voltage between the at least one of the HV potentials on the one hand and the ground potential on the other hand. In this case, use is made of at least one voltmeter which is connected to the insulation monitor or is part of it. Alternatively, it is possible to use at least one voltmeter which is evaluated by its own evaluation circuit. This voltmeter has no direct signal-transmitting connection to the insulation monitor. In other words, provision may be made for the voltmeter used here to not be evaluated by the insulation monitor.

Therefore, if a potential difference which results from the current flow through the voltage limiting circuit is determined, this can be carried out by at least one voltmeter and its own evaluation circuit connected to it, which are at least logically separate from the insulation monitor. The voltmeter in question and the evaluation circuit hereby form an autonomous unit which is provided, for example, within a high-voltage housing in which other components of the high-voltage on-board electrical system branch are also present, for example HV switches and/or an HV storage battery, possibly also an HV voltage converter and/or an HV charging circuit.

At least one of the following measures can be carried out if the insulation fault is identified by identifying a current flow through the voltage limiting circuit. As a measure, provision may be made for a high-voltage storage battery of the HV on-board electrical system branch to be disconnected from the remaining HV on-board electrical system branch by means of circuit breakers. Provision can also be made for at least one Cy capacitor of the HV on-board electrical system branch to be disconnected, in particular the Cy filter capacitors of an inverter and/or a traction motor. Alternatively or additionally, provision may be made, as a measure, for a charging post connected to the HV on-board electrical system to be disconnected. Provision can also be made for the HV on-board electrical system branch to be discharged (in particular to ground potential) as a measure. Finally, as a measure, provision may be made for an HV on-board electrical system sub-branch to be disconnected from an inverter HV on-board electrical system sub-branch. In this case, the inverter HV on-board electrical system sub-branch has the traction inverter. This can be provided in particular by disconnecting the inverter HV on-board electrical system sub-branch. The inverter HV on-board electrical system sub-branch has the traction inverter and/or an electric machine that is used for traction of the vehicle.

If, for example, a Cy filter capacitor is disconnected when an insulation fault is detected, this results in a poorer EMC filter property. However, the disconnection avoids excessively high contact voltages.

Provision can be made for the voltage limiting circuit, whose current flow is identified, to be connected between the ground potential and a positive LV potential which (normally) carries a positive supply potential of the LV on-board electrical system.

Furthermore, provision can be made for the voltage limiting circuit, whose current flow is identified, to be connected between the ground potential and a (positive) LV potential which is a line potential of the LV on-board electrical system. Such a line potential can be a potential of a sensor line or of a communication line or of a control line.

An LV device can be connected to the ground potential and to a positive supply potential of the LV on-board electrical system branch. This connection can be provided via a first connection side. In addition, at least one line can be connected to another connection side, for example to an interface of the LV device, wherein this line may have a (positive) LV potential (or a potential that differs from ground). A plurality of lines can be connected to this side, wherein at least one of the lines has the LV potential which differs from ground and is usually positive. For example, this can be a signal line. The voltage limiting circuit can be connected between a ground potential and a conductor, which is, for example, a conductor of a sensor line or of a communication line. According to one embodiment, the line to which the voltage limiting circuit is connected is not necessarily a positive LV potential in the sense of a positive supply potential, but can be a signal line, for example.

The LV device may be an LV communication apparatus, for instance a CAN bus circuit, or an LV sensor apparatus, for example a temperature, current or voltage measuring unit. Furthermore, the LV device can be an LV control device. In this case, the line or the LV potential to which the voltage limiting circuit is connected can be a control line or a conductor that is part of a control line.

Finally, the voltage limiting circuit, whose current flow is measured, can have a varistor, a gas discharge tube, a spark gap, a protective diode, a thyristor circuit, a DIAC, a Zener diode and/or a four-layer diode. The voltage limiting circuit is generally configured to conduct above a limit voltage (=breakdown voltage) and not to conduct below a limit voltage. Therefore, the current flow indicates an excessive voltage, that is to say a voltage that is above the limit voltage or breakdown voltage. The components mentioned can also be provided in any combination of the voltage limiting circuit.

The voltage limiting circuit can be connected between the ground potential and an LV potential and can be connected via a fuse to that section of the LV on-board electrical system branch in which a low-voltage storage battery is located. This allows the fuse to blow if the insulation is defective, while the voltage limiting circuit continues to provide a current flow due to the reduced insulation resistance, which current flow can be detected and used to output a fault. The fuse then serves to protect the LV device and in particular the interface of the LV device that is connected via the fuse.

Furthermore, it is possible to provide an on-board electrical system which is configured to carry out the method, in particular in which the on-board electrical system is configured to detect an insulation fault in the vehicle on-board electrical system, has an HV on-board electrical system branch and an LV on-board electrical system branch, the LV on-board electrical system branch has a positive supply potential and a negative supply potential, wherein this corresponds to a ground potential (M) of the vehicle on-board electrical system, and wherein the HV on-board electrical system branch has a positive HV potential and a negative HV potential which are DC-isolated from the potentials of the LV on-board electrical system branch. The on-board electrical system is also configured to detect an insulation fault between at least one of the HV potentials and a positive LV potential by identifying a current flow through a voltage limiting circuit, wherein the on-board electrical system has such a voltage limiting circuit which is connected between the ground potential and the positive LV potential. Furthermore, the on-board electrical system can have apparatus features that are mentioned in the context of the method described here, and the on-board electrical system can be configured to implement the method features described here.

### BRIEF DESCRIPTION OF THE DRAWINGS

The FIGURE serves to explain the method described here in more detail and shows an on-board electrical system circuit provided for carrying out the method.

### DETAILED DESCRIPTION OF THE PREFERRED EMBODIMENTS

The FIGURE shows a vehicle on-board electrical system FB having a low-voltage storage battery NA which is connected to an HV on-board electrical system branch HB via a low-voltage converter. The HV on-board electrical system branch LB is connected via the converter NW to the LV on-board electrical system branch LB which also contains the low-voltage storage battery NA. A high-voltage storage battery HA is provided in the high-voltage on-board electrical system branch HB and is connected via an isolating apparatus TS and via a storage battery connection BA. The storage battery connection BA is located between the high-voltage storage battery HA and the circuit breakers TS. The circuit breakers are designed with two poles.

Cy capacitors Cy1, Cy2 are also located in the high-voltage on-board electrical system HB. These are located between the ground potential M and the negative HV potential HV−, or between the ground potential M and the positive HV potential HV+. A negative LV potential L−, which corresponds to the ground potential M, is provided in the low-voltage on-board electrical system branch LB. The ground potential M preferably in turn corresponds to the chassis potential of the vehicle. A positive LV potential L, which corresponds to a supply potential, is also provided.

The two supply potentials L−, L+ of the HV on-board electrical system branch supply a low-voltage device NG, for example a sensor evaluation circuit. The sensor evaluation circuit also comprises a line L with a positive LV potential G+ and a negative LV potential G−. The potential G− can correspond to the potential L− or M. The positive potential G+ is a positive line potential, but may generally be a line potential, for example as the potential of a signal conductor. The low-voltage device NG can also be referred to as an LV device.

As shown, the line L can be continued and lead to other components, for example to other sensors. For example, the low-voltage device NG can be a communication apparatus, for example a CAN bus circuit, to which a plurality of further components are connected. In particular, the line can lead out of a housing in which HV components are located and can in particular be routed out into an area in which LV components or conductors with ground potential are located. It would be critical if the line carried HV potential since this can come into contact with ground or LV components, especially since the line is equipped for LV applications and thus does not have the insulation used for HV components.

A voltage limiting circuit SG is provided in order to prevent an insulation fault from propagating into the potential G+, that is to say generally into a signal potential of the LV on-board electrical system branch LB. If there is an insulation fault in the form of an associated resistance RF, compare dot-dashed connection, the positive HV potential + is connected to the potential G+ via this faulty insulation resistance and thus to a conductor or line L which belongs to the LV on-board electrical system branch and can lead to other components. As a result, other components of the LV on-board electrical system can also be loaded with the HV potential +, which leads to possibly dangerous contact voltages on other LV components.

The voltage limiting circuit SG is used to generate a current flow I in a targeted and predictable manner when an HV potential (+) crosses over into the LV on-board electrical system LB via the insulation fault RF. The current flow I is shown with a dashed line. On the one hand, the resulting potential shift between ground potential M and one of the HV potentials+, − can be detected. On the other hand, the current flow I can also be detected by an ammeter. Preferably, the shift is detected by considering a change rate resulting from the sudden occurrence of the insulation resistance RF. This change rate is significantly faster than the change rate of the potential +, − with respect to M, which occurs due to the test current during an active insulation measurement. In addition, due to the voltage limiting circuit and its breakdown voltage, from which it conducts, there is a different potential offset of the HV potentials+, − with respect to the ground potential M. In particular, this offset is greater than with the charge reversal or discharging that occurs during the active insulation resistance measurement and the offset is also established more quickly (i.e. has a higher voltage change rate). In this way, the resulting voltage, which corresponds to the breakdown voltage of the voltage limiting circuit, can be clearly separated from the minimum voltage which minimally results during the active insulation resistance measurement.

The breakdown voltage of the voltage limiting circuit is smaller by a minimum margin than the minimum voltage that occurs during the active insulation resistance measurement. As a result, the faults can be detected separately from one another; in particular, a fault can be detected as shown (connection between HV+ and an LV signal line).

An insulation monitor IM can be provided. This can be connected to voltmeters V1, V2 which capture the voltage between the HV potential + and ground M or between the HV potential − and ground M. With these, the insulation monitoring IM can actively measure the insulation resistance. Furthermore, provision may be made for these voltmeters V1, V2 to also be used to carry out the method described here, for example by measuring the potential change rate or the resulting potential shift. However, voltmeters that are independent of the insulation monitoring circuit IM are preferably used, wherein an evaluation circuit is also connected to these voltmeters, wherein the voltmeters and the evaluation circuit are configured to carry out the method described here, independently of the active insulation resistance measurement of the insulation monitoring circuit IM.

Finally, a charging device LG is shown, which is connected to a charging connection LA via a three-phase line. A charging post LS can be connected to the charging connection LA.

If a current flow is identified according to the method, provision may be made for the circuit breakers TS to be opened in order to thus disconnect the HV storage battery HA. Alternatively or additionally, provision may be made for the charging circuit LG to suppress or interrupt a charging process. In addition, provision may be made for an active insulation resistance measurement to be prevented by the insulation monitoring circuit IM, in particular the injection of a test current for detecting the insulation resistance.

Finally, it should be noted that the insulation monitoring circuit IM monitors the insulation resistance between the potential M on the one hand and the potentials +, − on the other hand, in particular by actively injecting a test current and determining the corresponding expected potential shift. This active insulation resistance measurement differs from the detection of a current flow I through the voltage limiting circuit SG, since the latter identifies an insulation fault in the high-voltage on-board electrical system branch HB with respect to the low-voltage on-board electrical system branch LB or the line L, even if the connection between the potentials G+ and L+ is broken (e.g. a burnt-out transistor in the low-voltage device NG).

The insulation fault RF can be considered to be a state and the resistance that triggers it.

1. A method for detecting an insulation fault in a vehicle on-board electrical system having an HV on-board electrical system branch and an LV on-board electrical system branch, wherein the LV on-board electrical system branch has a positive supply potential and a negative supply potential that corresponds to a ground potential of the vehicle on-board electrical system, and the HV on-board electrical system branch has a positive HV potential and a negative HV potential which are DC-isolated from the potentials of the LV on-board electrical system branch, wherein an insulation fault between at least one of the HV potentials and a positive LV potential is detected by identifying a current flow through a voltage limiting circuit connected between the ground potential and the positive LV potential.

2. The method as claimed in claim 1, wherein the current flow is identified on the basis of a shift of one of the HV potentials with respect to the ground potential.

3. The method as claimed in claim 2, wherein the current flow is identified on the basis of a potential change rate that is above a predetermined value.

4. The method as claimed in claim 2, wherein the current flow is identified on the basis of a change to a potential difference between the HV potential and the ground potential that is below a predetermined value, wherein this potential difference occurs while the voltage between the HV potentials is within a normal range.

5. The method as claimed in claim 2, wherein the shift is identified by an insulation monitor.

6. The method as claimed in claim 5, wherein the insulation monitor also carries out an active insulation test of the HV on-board electrical system branch by actively reversing the charge of Cy capacitances between the ground potential on the one hand and the HV potentials on the other hand and detecting a potential shift caused by the charge reversal, wherein the active charge reversal is interrupted when a current flow through the voltage limiting circuit is identified.

7. The method as claimed in claim 6, wherein, during the active charge reversal, a potential difference between one of the HV potentials and the ground potential does not drop below a minimum voltage and the current flow through the voltage limiting circuit is identified on the basis of a change to a potential difference between the HV potential and the ground potential that is below a predetermined value, wherein this value is smaller than the minimum voltage.

8. The method as claimed in claim 5, wherein the current flow through the voltage limiting circuit is identified by measuring at least one voltage between at least one of the HV potentials on the one hand and the ground potential on the other hand by at least one voltmeter which is connected to the insulation monitor or by at least one voltmeter which is evaluated by its own evaluation circuit and has no direct signal-transmitting connection to the insulation monitor.

9. The method as claimed in claim 1, wherein at least one of the following measures is carried out if the insulation fault is identified by identifying a current flow through the voltage limiting circuit:
disconnecting a high-voltage storage battery of the HV on-board electrical system branch from the remaining HV on-board electrical system branch by circuit breakers;
disconnecting at least one Cy filter capacitor of the HV on-board electrical system;
disconnecting a charging post connected to the HV on-board electrical system;
discharging the HV on-board electrical system branch; and
disconnecting an HV on-board electrical system sub-branch from an inverter HV on-board electrical system sub-branch which has a traction inverter.

10. The method as claimed in claim 1, wherein the voltage limiting circuit, whose current flow is identified, is connected between the ground potential and a positive LV potential which is a positive supply potential of the LV on-board electrical system branch.

11. The method as claimed in claim 1, wherein the voltage limiting circuit, whose current flow is identified, is connected between the ground potential and a positive LV potential which is a positive line potential of the LV on-board electrical system branch.

12. The method as claimed in claim 11, wherein an LV device is connected to the ground potential and to a positive supply potential of the LV on-board electrical system branch, and wherein lines are connected to the LV device, wherein at least one of the lines has a positive LV potential.

13. The method as claimed in claim 12, wherein the LV device is an LV communication apparatus or an LV sensor apparatus or an LV control device.

14. The method as claimed in claim 1, wherein the voltage limiting circuit, whose current flow is measured, comprises a varistor, a gas discharge tube, a spark gap, a protective diode, a thyristor circuit, a DIAC, a Zener diode and/or a four-layer diode.
